(19) United States
(12) Patent Application Publication
(10) Pub. No.: US 2024/0377729 A1
(43) Pub. Date: Nov. 14, 2024

(54) ORGANOTIN PHOTORESIST COMPOSITION AND METHOD OF STABILIZATION

(71) Applicant: Feng Lu, Irvine, CA (US)

(72) Inventor: Feng Lu, Irvine, CA (US)

(21) Appl. No.: 18/394,570

(22) Filed: Dec. 22, 2023

Related U.S. Application Data
(60) Provisional application No. 63/465,610, filed on May 11, 2023.

(51) Int. Cl. G03F 7/004; C07F 7/22

(52) U.S. Cl. CPC G03F 7/0042; C07F 7/2224

(57) ABSTRACT

An organotin photoresist composition for actinic radiation and a method of stabilization are described. The organotin photoresist composition comprises an organotin compound represented by chemical formulas [RSnOO]₄Sn, [RSnOO]₃SnR¹, [RSnOO]₂SnR¹₂, [RSnOO]SnR¹₃, [R₃SnO]₄Sn, [R₃SnO]₃SnR¹, [R₃SnO]₂SnR¹₂, [R3SnO]_{SnR}¹₃, or R₂Sn(μ-O)₂Sn(μ-O)₂SnR₂, a solvent and an additive, wherein R, R¹ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group. A method of stabilization of organotin photoresist composition comprises adding an organic additive.

### CROSS PEFERENCE TO RELATED APPLICATIONS

This application claims priority to U.S. provisional patent application No. 63/465,610, filed on May 11, 2023 to Lu, entitled “Organotin photoresist composition and method of stabilization”, of which is entirely incorporated herein by reference.

### FIELD OF INVENTION

The present invention relates to organotin photoresist composition for actinic radiation and a method of stabilization, particularly for extreme ultraviolet radiation (EUV) photolithography.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various metal-carbon bond (M-C) bond dissociation energy (BDE), and then can be used as photoresists and/or precursors for photolithography at smaller level (e.g., <7 nm), which is of great interests for radiation lithography. Among those promising advanced materials, particularly organometallic tin compounds can provide photoresist patterning with significant advantages, such as improved resolution, sensitivity, etch resistance, and lower line width/edge roughness without pattern collapse because of strong EUV radiation adsorption of tin, which have been demonstrated.

Organotin clusters have been demonstrated as EUV photoresists, which provide promising approach for the development of further smaller features such as <7 nm. However, the poor storage stability, poor solubility, and short shelf time with aggregation or precipitation formation during storage have become severe issues for distribution and application in photolithography patterning. In order to overcome the age and poor storage stability of as-formed organotin cluster photoresists, in situ hydrolysis and condensation have been developed for EUV photolithography patterning. For example, in situ hydrolysis of t-BuSnCl₃ with water or moisture on the surface of substrate forms organotin precursor or polynuclear oxo/hydroxo clusters [(t-BuSn)₁₂O₁₄(OH)₆] L₂.

Organic molecules containing various functional groups, such as —SH, —OH, —COOH, —NH₂, or phosphine, can be used as additives to stabilize organotin compounds, clusters, or nanoparticles photoresist with improved stability and/or solubility. The organic additives comprise organic thiol, organic alcohol, organic amine, organic amide, organic carboxylic acid, organic phosphine, organic phosphine oxide, or organic phosphonic acid, which can be adsorbed, grafted, immobilized, anchored or coordinated on organotin clusters and then avoid potential aggregation, precipitation, or age. For example, after exposure, the exposed portion of organic additive-stabilized organotin photoresists convert to polynuclear oxo-hydroxide network or metal oxides with poor solubility in solvents. While the unexposed portion of organotin photoresist can be removed by the developers, or appropriate methods such as sublimation or evaporation under ambient conditions (e.g., high vacuum and/or high temperature).

### SUMMARY

In a first aspect, the present invention pertains to organotin photoresist composition for actinic radiation and a method of stabilization, particularly for extreme ultraviolet (EUV) photolithography patterning. The organotin photoresist composition comprises an organotin compound, a solvent, and an additive.

In another aspect, the invention pertains to radiation sensitive organotin compounds represented by Chemical Formulas of [RSnOO]₄Sn, [RSnOO]₃SnR¹, [RSnOO]₂SnR¹₂, [RSnOO]SnR¹₃, [R₃SnO]₄Sn, [R₃SnO]₃SnR¹, [R₃SnO]₂SnR¹₂, [R₃SnO]SnR¹₃, or R₂Sn(μ-O)₂Sn(μ-O)₂SnR₂ as below:

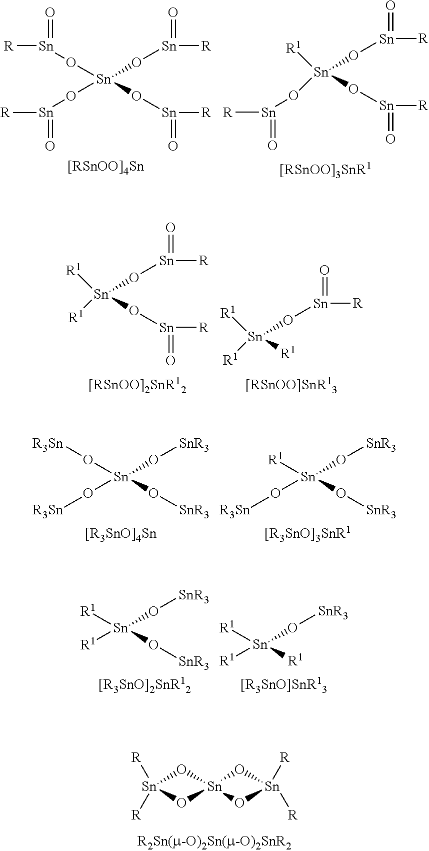

wherein R, R¹ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group.

In a further aspect, the present invention pertains to a method of stabilization; wherein an organic additive stabilizes organotin photoresist composition for photolithography patterning. Organic additive stabilization may overcome the disadvantages like poor stability and solubility and/or short shelf time from non-stabilized conventional organotin photoresists. The method of stabilization comprises the addition of organic additive to stabilize the as-formed organotin compounds, particularly organotin clusters or nanoparticles, and to prevent from aggregation occurred or precipitate formation. The aggregation and precipitation can lead to scums or defects on the surface of substrates during photolithography patterning. The organic additives contain various functional groups such as —SH, —OH, —NH₂, —COOH, —CONH₂, including but not limited to, organic thiol (e.g., 1-dodecanethiol), organic alcohol (e.g., 1,2-hexadecanediol, 2-mercaptoethanol), organic amine (e.g., 1-heptadecyloctadecylamine, octadecylamine), organic amide (e.g., dodecanamide), organic carboxylic acid (e.g., oleic acid), organic phosphine (e.g., trioctylphosphine), phosphine oxide (e.g., trioctylphospine oxide), phosphonic acid (e.g., octadecylphosphonic acid), or combinations thereof.

In other aspects, the present invention is to provide preparation and purification methodology of organotin photoresist with high purity for photolithography (e.g., EUV, <7 nm). The present invention is further to provide an alternative organotin photoresist with higher resolution, sensitivity, and lower line width roughness without pattern collapse during microelectronic patterning. The sensitivity and stability of organotin compounds are important for high resolution and efficiency of photoresist for photolithography. The present invention is to provide improved stability, solubility, uniformity and shelf life of organic additive-stabilized organotin photoresist composition for substrate surface coating without aggregation, precipitation or age.

In an additional aspect, the invention pertains to the methods for organotin photoresist composition deposition on a surface of semiconductor substrate by wet deposition like spin-on coating, spray coating, dip coating, vapor deposition, knife edge coating, or dry deposition like chemical vapor deposition, physical vapor deposition, atomic layer deposition, or other approaches. After exposure to extreme ultraviolet light, ultraviolet light, e-beam radiation, X-ray radiation or other likes, the components, features or properties of organotin photoresist will change between exposed and unexposed portions. After development, the exposed or unexposed portions of organotin photoresist can be removed by appropriate developers such as organic solvent or aqueous solution.

The photosensitivity, thermostability and uniformity of organotin photoresist compositions determine high resolution and efficiency of photolithography. The organotin photoresist can dissolve in appropriate organic solvents to form uniformed solution composition for deposition on the surface of substrate for photolithography patterning. The organic solvents include but not limited to aromatic solvents (e.g., benzene, toluene, xylene), pentane, hexane, cyclohexane, tetrahydrofuran, dimethoxyethane, alcohol (e.g., methanol, ethanol, propanol, butanol), ether (e.g., diethyl ethers, anisole), ester (e.g., ethyl acetate, ethyl lactate), methylene chloride, chloroform, or combinations thereof.

The invention pertains to radiation sensitive organometallic tin precursors for preparation of organotin photoresists, including but not limited to, alkyl-, alkenyl-, alkynyl-, cycloalkyl-, cycloalkenyl-containing organometallic tin compounds. The hydrolysable organometallic tin precursors for generation of organotin photoresist, include, but not limited to, oxide hydroxide (stannonic acid), anhydride, hydroxide, alkoxides, amides, distannoxane (oxo), oxides, esters, or halides. In some embodiments, organometallic tin precursor is one or more selected from the following:

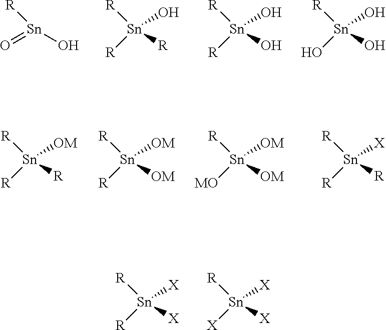

wherein R is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group, M=Li, Na, or K; X═F, Cl, Br, or I.

In some embodiments, cycloalkenyl group comprises a substituted and unsubstituted C4 to C8 aliphatic unsaturated organic groups including at least one double bond. In some embodiments, cycloalkenyl group is one selected from the following:

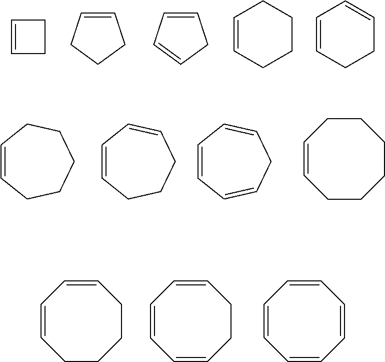

In further embodiments, cycloalkenyl group comprises a cyclopentadienyl (C₅H₅, or Cp) group, or a substituted cyclopentadienyl (C₅H₄R, C₅H₃R₂, C₅H₂R₃, C₅HR₄, or C₅R₅) group with different hapticity of η¹, η², η³, η⁴, or η⁵ of isomers, a cycloheptatrienyl (C₇H₇) group, or a substituted cycloheptatrienyl (C₇H₆R, C₇H₅R₂, C₇H₄R₃, C₇H₃R₄, C₇H₂R₅, C₇HR₆, or C₇R₇) group with different hapticity of η¹, η², η³, η⁴, η⁵, η⁶, or η⁷ of isomers, wherein R is H, a substituted or unsubstituted alkyl, alkenyl, alkynyl, or a cycloalkyl group with 1 to 20 carbon atoms, or a substituted or unsubstituted aryl group with 6-20 carbon atoms, or other functional groups including an amine, cyano, ether, cyclic ether, ester, cyclic ester, halide, nitro, silyl, thiol, or carbonyl group.

The invention relates to radiation sensitive organotin photoresist composition, which can be efficiently patterned after exposure to ultraviolet light, extreme ultraviolet light, electron beam radiation, X-ray radiation or other likes to form high resolution patterns with low line width roughness, high resolution, low dose and large contrast, such as for <7 nm.

Furthermore, the present invention pertains to the methods for purification of organotin compounds. The purification methods include distillation, extraction, filtration, recrystallization, column chromatography, coordination, sublimation, or combinations thereof.

### BRIEF DESCRIPTION OF THE DRAWINGS

FIG. 1 is Chemical Formulas of organotin compounds as photoresists, wherein R, R¹ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group.

FIG. 2 illustrates a flowchart of organotin photoresist radiation photolithography patterning processing on the surface of semiconductor substrate surface.

### DETAILED DESCRIPTION

The present invention pertains to organotin photoresist composition and a method of stabilization. The present invention is to provide organotin photoresists and the stabilization method of organotin photoresist composition, particularly, for EUV lithography (e.g. <7 nm). The present invention is further to provide organotin photoresist composition with higher resolution, sensitivity, solubility, stability, shelf life, and lower line width roughness without pattern collapse during microelectronic patterning. The photosensitivity and thermostability of organotin photoresist determine high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, or “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The terms “alkenyl, alkynyl, cycloalkyl” refers to hydrocarbon of 1 to 20 carbon atoms. The term “aryl” refers to unsubstituted or substituted aromatic group with 6-20 carbon atoms. The substituted group include, but not limited to, amide, amine, cyano, ether, cyclic ether, ester, cyclic ester, halide, imine, nitro, silyl, thiol, or carbonyl group. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), tertiary (—NR₂) amine group. The term “cyclic amine” refers to [R—NH—R′], wherein [R—R′] is cyclic substituted and unsubstituted C3 to C8 organic groups, including, but not limited to:

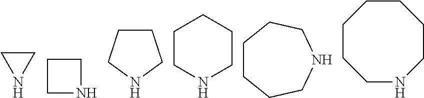

The term “ether” refers to the R—O—R′ group. The term “cyclic ether” refers to the [R—O—R′], wherein [R—R′] is cyclic substituted and unsubstituted C3 to C8 organic groups, including, but not limited to:

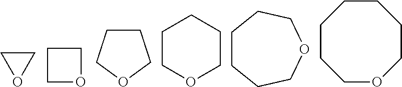

The term “ester” refers to the R—(C═O)—O—R′ group. The term “cyclic ester” refers to the [R—(C═O)—O—R′], wherein [R—R′] is cyclic substituted and unsubstituted C4 to C8 organic groups, including, but not limited to:

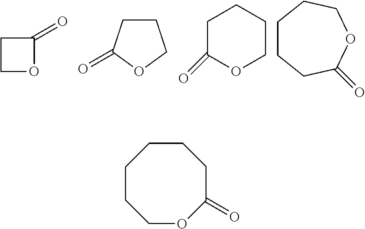

The term “halide” refers to the F, Cl, Br, or I. The term “nitro” refers to the —NO₂. The term “silyl” refers to the —SiR—, —SiR₂—, or —SiR₃ group. The term “thiol” refers to —SH group. The term “carbonyl” refers to the —C═O group. The term “oxo” refers to —O—, or ═O.

In the present disclosure, the term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant groups.

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light adsorption, low resolution, high line edge roughness (LER), increased pattern collapses and defects. In order to overcome the disadvantages from conventional organic polymer photoresists or inorganic photoresists, novel organometallic photoresists, or organometallic photosensitive compositions, particularly for EUV, have been called for.

Organometallic photoresists are used in EUV lithography because metals have high adsorption capacity of EUV radiation. Radiation sensitivity and thermal-, oxygen-and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the photolithography performance, lead to pattern collapse, and increase defects.

In general, metal central plays the key role in determining the absorption of photo radiation of organometallic photoresists. The physical and chemical properties of organometallic compounds which are suitable for photoresists determine the relevant properties for photolithography, particularly for EUV and DUV, wherein bond dissociated energy (BDE) of M-C (metal-carbon bond) plays the key role. M is metal, including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organotin photoresists are suitable for EUV or DUV photolithography patterning.

Meanwhile for organometallic compounds, the metal-bonded organic ligands (M−R, M=metal, R=cleavable/hydrolysable organic ligands) may also influence the relevant absorption through M-C bonding.

Tin atom provides strong absorption of extreme ultraviolet (EUV) light at 13.5 nm, therein tin cations can be selected based on the desired radiation and absorption cross section. Meanwhile the organic ligand bonded to tin also has absorption of EUV light. Therefore, the tuning and modification of organic ligands can change sensitivity, radiation absorption, or the desired control of material properties.

The bond dissociation energy (BDE) of Sn—C bond determines the light adsorption wavelength, corresponding smaller features, and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability compared with conventional organic polymer or inorganic photoresists.

In some embodiments, organotin photoresist comprises small organometallic tin compound, or organotin cluster with large molecular weight. In some embodiments, the small organometallic tin compound contain one, two, or three tin atoms. In some embodiments, organotin cluster contain more than three tin atoms, for example, twelve.

The organotin cluster photoresists comprise organic ligand, Sn—C bond, Sn—O bond, or Sn—O—Sn bond providing desirable radiation sensitive and stabilization for photolithography patterning. The organotin cluster photoresists possess excellent properties for the application of photolithographic patterning.

Organotin photoresist composition according to embodiments of the present disclosure may have relatively improved etch resistance, sensitivity and resolution, compared with related conventional organic polymer and inorganic resists, wherein oxygen, nitrogen, or various groups are bonded to tin metal as described above.

Organotin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation (e.g., EUV) becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

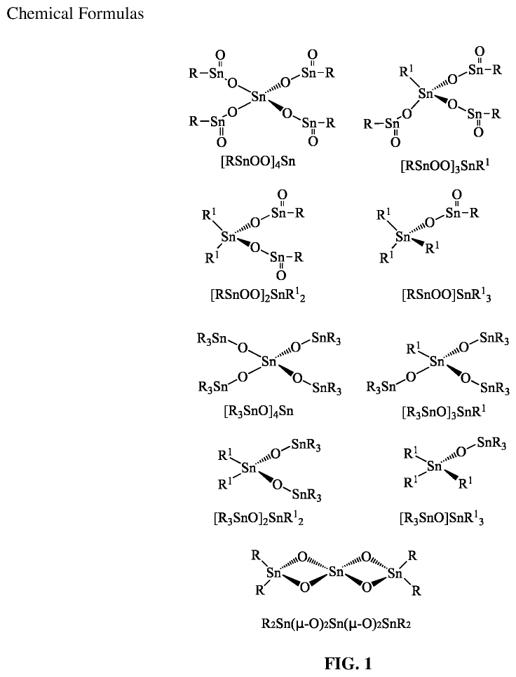

In the present invention disclosure, organotin photoresists are represented by Chemical Formulas of FIG. 1, including [RSnOO]₄Sn, [RSnOO]₃SnR¹, [RSnOO]₂SnR¹₂, [RSnOO]SnR¹₃, [R₃SnO]₄Sn, [R₃SnO]₃SnR¹, [R₃SnO]₂SnR¹₂, [R₃SnO]SnR¹₃, or R₂Sn(μ-O)₂Sn(μ-O)₂SnR₂ shown as below:

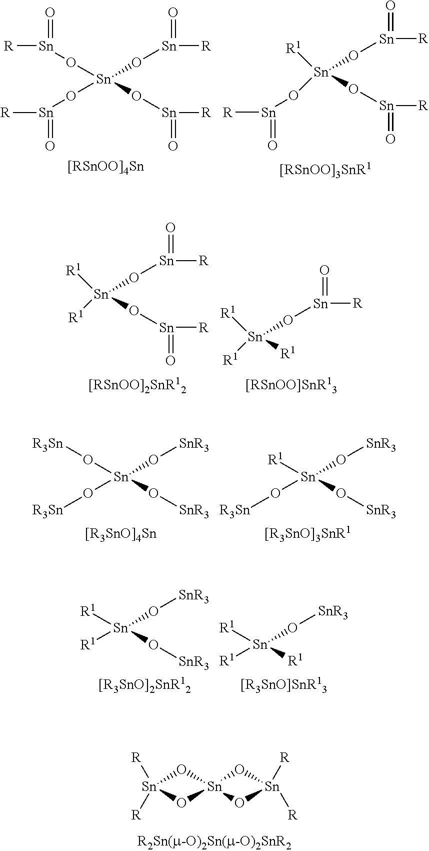

wherein R, R¹ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group.

In some embodiments, organotin photoresists according to embodiments of the present disclosure may be represented by at least one of examples. Examples of specific organotin compound photoresists that may be used in implementations of the invention, represented by chemical formulas of FIG. 1.

Cycloalkenyl group comprises a substituted and unsubstituted C4 to C8 aliphatic unsaturated organic groups including at least one double bond, for example, cyclopentadienyl, cycloheptatrienyl, or cyclooctatetraene. Cyclopentadienyl comprises cyclopentadienyl C₅H₅ group, or substituted cyclopentadienyl C₅H₄R², C₅H₃R²₂, C₅H₂R²₃, C₅HR²₄, or C₅R²₅ group with hapticity of η¹, η², η³, η⁴, or η⁵ of isomers, wherein R² is H, an alkyl, alkenyl, or alkynyl group with 1 to 20 carbon atoms, or cycloalkyl group with 3 to 20 carbon atoms, or an aryl group with 6-20 carbon atoms, or an amine, cyano, ether, cyclic ether, ester, cyclic ester, halide, nitro, silyl, thiol, or carbonyl group.

For example, in some embodiments, R is an alkyl, aryl, or cyclopentadienyl group, R¹ is cyclopentadienyl group, wherein cyclopentadienyl comprises cyclopentadienyl C₅H₅, or substituted cyclopentadienyl C₅H₄R², C₅H₃R²₂, C₅H₂R²₃, C₅HR²₄, or C₅R²₅ with hapticity of η¹, η², η³, η⁴, or η⁵ of isomers, wherein R² is methyl, ethyl, n-propyl, iso-propyl, n-butyl, iso-butyl, sec-butyl, t-butyl, phenyl, or benzyl.

As one of ordinary skill in the art will recognize, the chemical compounds listed here are merely intended as illustrated examples of the organotin compounds including clusters, and are not intended to limit the embodiments to only those organotin compounds specifically described. Rather, any suitable organotin compounds may be used, and all such organotin compounds are fully intended to be included within the scope of the present embodiments.

In the present disclosure, organotin compounds represented by FIG. 1 may be synthesized according to appropriate methods. The inert atmosphere (e.g., dried nitrogen or argon), and dried solvents without moisture or water with standard Schlenk techniques are required.

In one example embodiment, the reactions of organotin oxide hydroxide RSnO(OH) with SnX₄, R¹SnX₃, R¹₂SnX₂, or R¹₃SnX (X═F, Cl, Br, or I) result in [RSnOO]₄Sn, [RSnOO]₃SnR¹, [RSnOO]₂SnR¹₂, or [RSnOO]SnR¹₃, respectively, in the presence of base (e.g., trimethylamine) under ambient conditions as below:

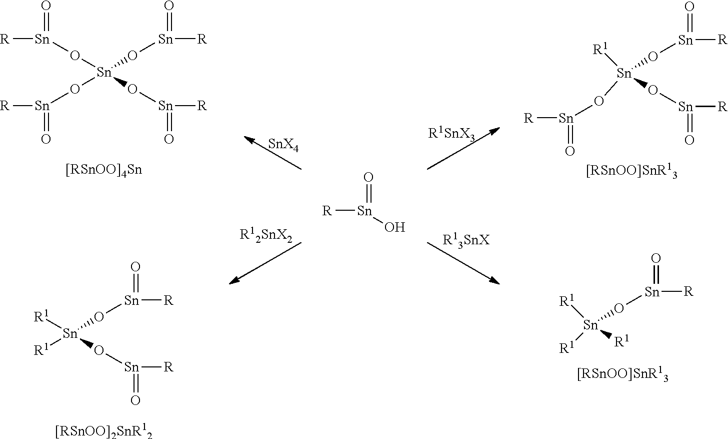

In one example embodiment, the reactions of R₃SnOM (e.g., M=Li, Na, or K) with SnX₄, R¹SnX₃, R¹₂SnX₂, or R¹₃SnX; or the reactions of R₃SnOH with SnX₄, R¹SnX₃, R¹₂SnX₂, or R¹₃SnX in the presence of base (e.g., trimethylamine) result in [R₃SnO]₄Sn, [R₃SnO]₃SnR¹, [R₃SnO]₂SnR¹₂, or [R₃SnO]SnR¹₃, respectively, under ambient conditions as below:

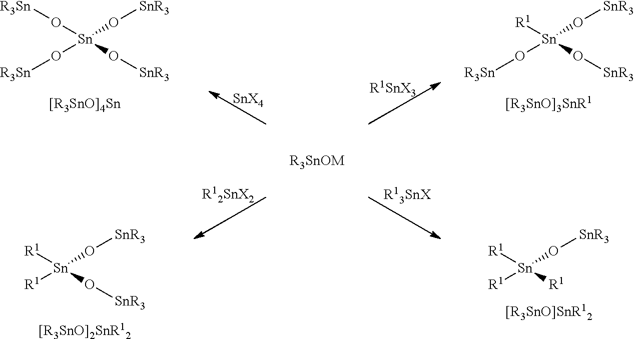

In some embodiments, R₃SnOM includes R^{a}R^{b}R^{c}SnOM, wherein R^{a}, R^{b}, R^{c} are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group, for example, Cp(^{t}Bu)(Ph)SnOLi, Cp₂(^{t}Bu)SnONa.

In another example embodiment, the reaction of R₂Sn(OH)₂ with SnX₄ in the presence of base (e.g., trimethylamine), or the reaction of R₂Sn(OM)₂ (e.g., M=Li, Na, or K) with SnX₄ results in R₂Sn(μ-O)₂Sn(μ-O)₂SnR₂ under ambient conditions as below:

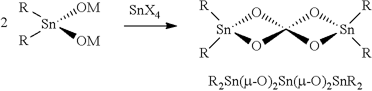

Wherein R, R¹ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group.
In some embodiments, R₂Sn(OH)₂, or R₂Sn(OM)₂ include R^{a}R^{b}Sn(OH)₂, R^{a}R^{b}Sn(OM)₂, wherein R^{a}, R^{b} are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group, for example, Cp(^{t}Bu)Sn(OH)₂, Cp(^{t}Bu)Sn(OLi)₂. A person of ordinary skills in the art will recognize that the synthetic strategies, reagents, solvents, or reaction conditions including reactant ratios, temperature, reaction time, or addition manner within the

In the present disclosure, the purification methods include, but not limited to, distillation, extraction, filtration, recrystallization, column chromatography, coordination, sublimation, and combinations thereof. For example, recrystallization can be carried out by slowly cooling down the hot solution of compounds to ambient temperature (e.g., 110° C. to room temperature). The solvents for recrystallization include, but not limited to, hexane, petroleum ether, diethyl ether, THF, benzene, toluene, ethanol, or combinations thereof. In some embodiments, recrystallization may result in single crystals, which are suitable for X-ray diffraction analysis for determining the related molecular structures. The column chromatography is usually carried out with silicon or aluminum oxide under air or inert atmosphere. In some embodiments, a short pad column is applied for fast purification of the products. In some embodiments, fractional distillation is used to purify the liquid products under reduced pressure. In some embodiments, sublimation or evaporation can be conducted under high vacuum and temperature without decomposition.

In some embodiments, the hydrolysable organic ligands of organometallic tin photoresist precursors carry out hydrolysis with water or moisture from promoting agent to form free hydroxyl (—OH) groups, and then condensation n to form organotin clusters, for example, [(RSn)₁₂O₁₄(OH)₆]L₂, R is organic ligand, L is anion.

In some embodiments, the radiation sensitive organotin cluster photoresists comprise polynuclear oxo, oxo-hydroxide networks, or cleavable or hydrolysable organic ligands. However, the poor stability of organotin cluster photoresist composition after aged would lead to aggregation, coagulation, or precipitation with short shelf life, which may result in scums or defects in photolithography patterning, and limit the real application in photolithography patterning. A method of in situ hydrolysis over the substrate therefore has been developed recently.

In some embodiments, the stability of organotin photoresist in solution can be improved by adding organic molecule as stabilizing additive. The organic additive-stabilized organotin photoresist composition possess improved stability, solubility, uniformity, or shelf life for photolithography patterning.

In some embodiments, organic molecule as stabilizing additive includes, but not limited to, organic thiol, organic alcohol, organic amine, organic amide, organic carboxylic acid, organic phosphine, phosphine oxide, or organic phosphonic acid. A person of ordinary skills in the art will recognize that the choice of organic molecules, concentrations, and solution composition components within the explicit ranges of above are contemplated and are within the present disclosure. For example, organic linear thiol 1-dodecanethiol has been demonstrated to stabilize Pd nanoparticles with high catalytic activity and stability, e.g., F. Lu, “Ligand-free, copper-free Sonogashira reaction and styrene hydrogenation catalyzed by 1-dodecanethiolate stabilized palladium nanoparticles”, Journal of Coordination Chemistry, 2021, 2534-2541, of which is incorporated herein by reference.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or combinations thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or combinations thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or combinations thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or combinations thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or combinations thereof.

In some embodiments, organic phosphine, phosphine oxide, or organic phosphonic acid include, but not limited to, trioctylphosphine, tributylphosphine, tris(dimethylamino) phosphine, tris(diethylamino) phosphine, trioctylphospine oxide, hexylphosphonic acid, octadecylphosphonic acid, 11-undecenyl phosphonic acid, or combinations thereof.

In some embodiments, organotin clusters comprise Sn—O, Sn—S, Sn—N, Sn—P bond, or Sn—O—Sn network. In some embodiments, organic stabilizing additive may be adsorbed, grafted, immobilized, anchored, or coordinated on organotin clusters as supports. For example, organic thiolate may coordinate with tin of organotin clusters to form Sn-S bond, or support on the surface of organotin clusters, which will stabilize clusters.

In an embodiment, organometallic tin compound precursors for preparation of organotin photoresists, according to embodiments of the present disclosure, may be represented by at least one of examples. Examples of specific organometallic tin precursor materials that may be used in implementations of the invention including but not limited to, oxide hydroxide, alkoxide, amide, anhydride, halide, ester, or oxo, which contain hydrolysable functional groups, such as —NR₂, —OR, —X, or —OCOR.

In some embodiments, the present invention pertains to organotin photoresists bearing cycloalkenyl group, wherein cycloalkenyl group comprises a substituted and unsubstituted C4 to C8 aliphatic unsaturated organic groups including at least one double bond, for example cyclopentadienyl, cycloheptatrienyl, or cyclooctatetraene group. Organometallic (cyclopentadienyl)tin compounds comprise cyclopentadienyl (C₅H₅), or substituted cyclopentadienyl C₅H₄R, C₅H₃R₂, C₅H₂R₃, C₅HR₄, or C₅R₅ group with hapticity of η¹, η², η³, η⁴, or η⁵ of isomers. Organometallic (cycloheptatrienyl)tin compounds comprise cycloheptatrienyl (C₇H₇), or substituted cycloheptatrienyl C₇H₆R, C₇H₅R₂, C₇H₄R₃, C₇H₃R₄, C₇H₂R₅, C₇HR₆, or C₇R₇ group with the hapticity of η¹, η², η³, η⁴, η⁵, η⁶, η⁷ of isomers, wherein R is H, a substituted or unsubstituted alkyl, alkenyl, or alkynyl group with 1 to 20 carbon atoms, or cycloalkyl group with 3 to 20 carbon atoms, or a substituted or unsubstituted aryl group with 6-20 carbon atoms, or an amine, cyano, ether, ester, halide, nitro, silyl, thiol, or carbonyl group, for example, including, but not limited to, methyl, ethyl, isopropyl, tert-butyl, tert-amyl, sec-butyl, pentyl, hexyl, neopentyl, cyclohexyl, cyclopentyl, cyclobutyl, cyclopropyl, phenyl, or benzyl.

Cyclopentadienyl group (C₅R₅, or Cp) may impart photosensitivity to the compounds. The formed Cₚ—Sn bond may promote suitable solubility in organic solvent to cyclopentadienyl-containing organotin compound photoresist. Accordingly, Cₚ—Sn bond containing organotin compound photoresist, according to an embodiment, may have improved sensitivity, resolution and stability, and may suitable for EUV photoresists, and/or the precursors for EUV lithography to form tin oxide or tin oxide hydroxide film.

The organometallic (cyclopentadienyl)tin compound contains cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅⋅ radical. This study demonstrated cyclopentadienyl (C₅H₅) group or substituted cyclopentadienyl (C₅R₅) group has higher UV light sensitivity compared to alkyl (e.g., methyl, butyl) groups under identical conditions. This property is beneficial to decrease EUV light dose and increase resolution.

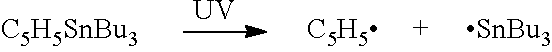

Organometallic (cyclopentadienyl)tin compound photoresists have excellent sensitivity to EUV radiation light due to the tin adsorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the organometallic (cyclopentadienyl)tin compound photoresist composition may have tight pitch (e.g., <10 nm), and may sustain the yield and deliver high resolution.

Organotin photoresist bearing cycloalkenyl group and C_{cycloalkenyl}—Sn bond, such as cyclopentadienyl or substituted-cyclopentadienyl group, according to embodiments of the present disclosure, may have improved etch resistance, sensitivity, and resolution, compared with C_{alkyl}—Sn containing organotin photoresist.

The organotin photoresist containing cyclopentadienyl group, π bond, Cₚ—Sn bond, and/or relevant interaction may have excellent sensitivity to high energy light. Accordingly, organotin photoresist may have improved sensitivity, solution, and stability compared with organic polymer photoresist or inorganic photoresist.

In some embodiments, organotin compounds are soluble in appropriate organic solvents with improved uniformity for photolithography pattern processing. The organotin photoresist composition can be formed by dissolving organotin photoresist in organic solvents, including but not limit to, pentane, hexane, cyclohexane, dichlomethane, chloroform, tetrahydrofuran, dimethoxyethane, dimethylformamide, dimethyl sulfoxide, alcohols (e.g., 4-methyl-2-pentenol, methanol, ethanol, propanol, isopropanol, butanol), aromatic solvent (e.g., benzene, toluene, xylene), carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. A person of ordinary skills in the art will recognize that the choice of solvents and solution composition components within the explicit ranges of above are contemplated and are within the present disclosure.

The organotin photoresist composition can be applied for photolithography including deep ultraviolet radiation (DUV), extreme ultraviolet radiation (EUV), e-beam radiation, X-ray radiation, or ion-beam radiation for further processing and patterning.

The general EUV photolithography process includes (1) to deposition photoresist as a thin film over the substrate; (2) then pre-exposure baking; (3) followed by exposing to EUV radiation to form a latent image; (4) after post-exposure baking; (5) then developed by the developer such as aqueous basic/acid solutions or organic solvents; (6) and then rinse with solvent to produce the developed resist pattern.

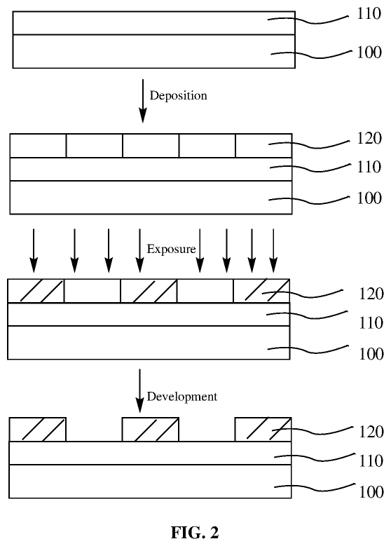

FIG. 2 is a flowchart of photolithography patterning process including organotin photoresists depositing over a substrate 110; followed by pre-exposure baking to form thin film 120; then exposing photoresist to actinic radiation (e.g., EUV) to form latent pattern; and then developing the selected portion to form latent pattern by developer or other appropriate methods such as sublimation or vaporization.

In some embodiments, after exposure, the exposed and unexposed portion of organotin photoresist composition possess different chemical and physical properties. Organic ligands of organotin photoresist can be cleaved from organotin photoresist to form metal oxide or polynuclear oxo/hydroxo network patterns. In some embodiments, the unexposed portion of photoresists can be removed by the developer due to different features, solubility and properties. In some embodiments, the selected portion may be removed by sublimation or evaporation under reduced pressure and/or high temperature to form the latent pattern.

Organic molecules as additives may stabilize the organotin photoresist composition, and avoid the aggregation or precipitation with extended shell life. As a result, the stability, solubility, and uniformity of organic additive-stabilized organotin photoresist composition can be improved during photolithography. Accordingly, a nanoscale pattern having improved stability, solubility, sensitivity and limited resolution may be afforded by using of organotin photoresist. Additionally, the as-formed pattern by using of organotin photoresist composition may not form scums and defects.

In summary, the application of organic molecules as additives provide an alternative and innovative approach to stabilize organotin photoresist compositions. Herein, the organotin photoresist includes organotin compound, organotin cluster, organotin nanoparticles, or organotin polymer photoresist. The stabilization method overcomes the issues of short shell life with aggregation, coagulation, precipitation, and scums or defects in photolithography patterning.

The composition of organotin photoresist according to embodiments of the present disclosure may have improved etch resistance, sensitivity and resolution, compared with conventional organic polymer or inorganic resists, wherein carbon, oxygen, nitrogen, or various groups are bonded to tin metal.

In addition, organic additive-stabilized organotin photoresist composition patterning according to an embodiment is not necessarily limited to the negative tone image but may be formed to have a positive tone image.

Hereinafter, the present invention is described in more details through Examples regarding the preparation of organotin photoresist composition and method of stabilization of present embodiments. However, the present invention is not limited by the Examples.

### EXAMPLES

### Example 1

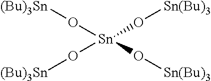

Synthesis of [(Bu)₃SnO]₄Sn. [(Bu)₃SnO]₄Sn was prepared by the reaction of Bu₃SnOLi with SnCl₄ at 0° C., which was according to the similar manner of the reference: C. Elschenbroich, F. Lu, M. Nowotny, O. Burghaus C. Pietzonka, and H. Klaus, Organometallics 2007, 26, 4025-4030. Bu₃SnOLi was freshly prepared through the reaction of Bu₃SnOH with equiv. lithium or n-BuLi at low temperature. At 0° C., under N₂ atmosphere, the solution of SnCl₄ (0.11 mL, 0.78 mmol) in tetrahydrofuran (20 mL) was added dropwise to the solution of Bu₃SnOLi (976 mg, 3.12 mmol) in THF (50 mL) with vigorously stirring in hour (Caution: SnCl₄ is extremely hydrolytic when exposure to air or water and releasing HCl gaseous!!!). After addition, the mixture was stirred at room temperature overnight and then evaporated in vacuum. The residue was extracted by toluene/THF and filtered through Celite. The filtrate was evaporated in vacuum to afford the product (0.53 g, yield 51%). ¹H NMR (298 K, 400 MHZ, CDCl₃) δ=1.33 (b, 108H). MS (EI): m/z 1342 (M⁺). Elemental analysis of C₄₈H₁₀₈O₄Sn₅ (1342.43), anal. calculated C: 42.94; H: 8.05; and found C: 42.62; H, 7.86.

### Example 2

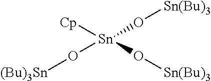

Synthesis of CpSn[OSn(^{t}Bu)₃]₃. (Cyclopentadienyl)tin trichloride ((C₅H₅)SnCl₃, or CpSnCl₃) was prepared according to the reference, U. Schroer, H.-J. Albert, and W. P. Neumann, Journal of Organometallic Chemistry 1975, 102, 291. At 0° C., to the solution of Bu₃SnOLi (1.0 g, 3.2 mmol) in THF (50 mL), the solution of CₚSnCl₃ (308 mg, 1.07 mmol) in THF (50 mL) was added dropwise with vigorously stirring. After addition, the mixture was stirred overnight. Then the mixture was evaporated in vacuum. The residue was extracted by toluene and filtered through Celite. The filtrate was evaporated in vacuum to afford the titled product (0.81 g, yield 69%). ¹H NMR (298 K, 400 MHz, CDCl₃) δ=5.98 (s, 5H), 1.35 (bs, 81H). MS (EI): m/z 1101 (M⁺). Elemental analysis of C₄₁H₈₆O₃Sn₄ (1101.25), anal. calculated C: 44.71; H: 7.81; and found C: 44.50; H, 7.36.

### Example 3

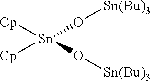

Synthesis of Cp₂Sn[OSn(Bu)₃]₂. Bis(cyclopentadienyl)tin dichloride ((C₅H₅)₂SnCl₂, or Cp₂SnCl₂) was prepared by the reaction of two equivalent C₅H₅Na with one equivalent SnCl₄ at low temperature under N₂ atmosphere, which was according to the reference: P. Jutzi, F. Kohl, Journal of Organometallic Chemistry 164 (1979) 141-152. At −20° C., to the solution of Bu₃SnOLi (504 mg, 1.61 mmol) in THF (50 mL), the solution of Cp₂SnCl₂ (1.03 g, 3.22 mmol) in THF (50 mL) was added dropwise with vigorously stirring. After addition, the mixture was stirred overnight. After removal of all the volatiles in vacuum, the residue was extracted by toluene and filtered through a short pad of silicon. The filtrate was evaporated in vacuum to afford the titled product (1.06 g, yield 76%). ¹H NMR (298 K, 400 MHZ, C₆D₆) δ=5.90 (s, 10H), 1.36 (s, 54H). MS (EI): m/z 861 (M⁺).

It is understood that the above-described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin photoresist composition for actinic radiation, comprising an organotin compound, a solvent, and an additive,
wherein the organotin compound is one or more selected from the following: 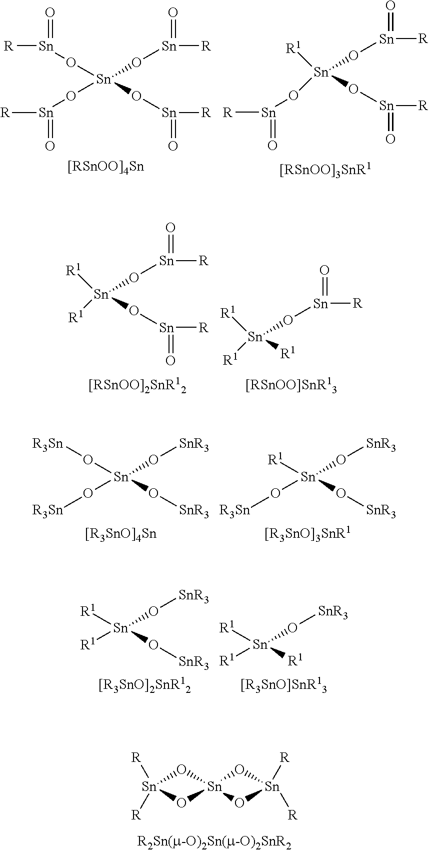
wherein R, R¹ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group.

2. The organotin photoresist composition of claim 1, wherein cycloalkenyl group comprises a substituted and unsubstituted C4 to C8 aliphatic unsaturated organic groups including at least one double bond.

3. The organotin photoresist composition of claim 2, wherein cycloalkenyl group comprises cyclopentadienyl C₅H₅ group, or substituted cyclopentadienyl C₅H₄R², C₅H₃R²₂, C₅H₂R²₃, C₅HR²₄, or C₅R²₅ group with hapticity of η¹, η², η³, η⁴, or η⁵ of isomers, wherein R² is H, an alkyl, alkenyl, or alkynyl group with 1 to 20 carbon atoms, cycloalkyl group with 3 to 20 carbon atoms, or an aryl group with 6-20 carbon atoms.

4. The organotin photoresist composition of claim 1, wherein R is alkyl, aryl, or cyclopentadienyl, R¹ is cyclopentadienyl; wherein cyclopentadienyl comprises cyclopentadienyl C₅H₅ group, or substituted cyclopentadienyl, C₅H₄R², C₅H₃R²₂, C₅H₂R²₃, C₅HR²₄, or C₅R²₅ group.

5. The organotin photoresist composition of claim 4, wherein R² is H, methyl, ethyl, propyl, butyl, phenyl, or benzyl.

6. The organotin photoresist composition of claim 4, wherein R is n-butyl, t-butyl, or cyclopentadienyl C₅H₅; R¹ is cyclopentadienyl C₅H₅.

7. The organotin photoresist composition of claim 1, wherein the solvent comprises benzene, toluene, xylene, tetrahydrofuran, dimethoxyethane, methanol, 4-methyl-2-pentano, ethanol, propanol, butanol, or combinations thereof.

8. The organotin photoresist composition of claim 1, wherein the additive comprises organic thiol, organic alcohol, organic amine, organic amide, organic carboxylic acid, organic phosphine, organic phosphine oxide, organic phosphonic acid, or combinations thereof.

9. The organotin photoresist composition of claim 1, wherein the actinic radiation comprises deep ultraviolet radiation, extreme ultraviolet radiation, e-beam radiation, X-ray radiation, or ion-beam radiation.

10. A method of stabilizing organotin photoresist composition, comprising:
adding an additive to an organotin photoresist composition.

11. The method of claim 10, wherein the additive comprises organic thiol, organic alcohol, organic amine, organic amide, organic carboxylic acid, organic phosphine, organic phosphine oxide, organic phosphonic acid, or combinations thereof.

12. The method of claim 11, wherein organic thiol comprises 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or combinations thereof.

13. The method of claim 11, wherein organic alcohol comprises 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or combinations thereof.

14. The method of claim 11, wherein organic amine comprises 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or combinations thereof.

15. The method of claim 11, wherein organic amide comprises decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or combinations thereof.

16. The method of claim 11, wherein organic carboxylic acid comprises oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or combinations thereof.

17. The method of claim 11, wherein organic phosphine, organic phosphine oxide, or organic phosphonic acid comprise trioctylphosphine, tributylphosphine, tris (dimethylamino) phosphine, tris (diethylamino) phosphine, trioctylphospine oxide, hexylphosphonic acid, octadecylphosphonic acid, 11-undecenyl phosphonic acid, or combinations thereof.

18. The method of claim 10, wherein the organotin photoresist composition comprises an organotin compound, and a solvent;
wherein the organotin compound is one or more selected from the following: 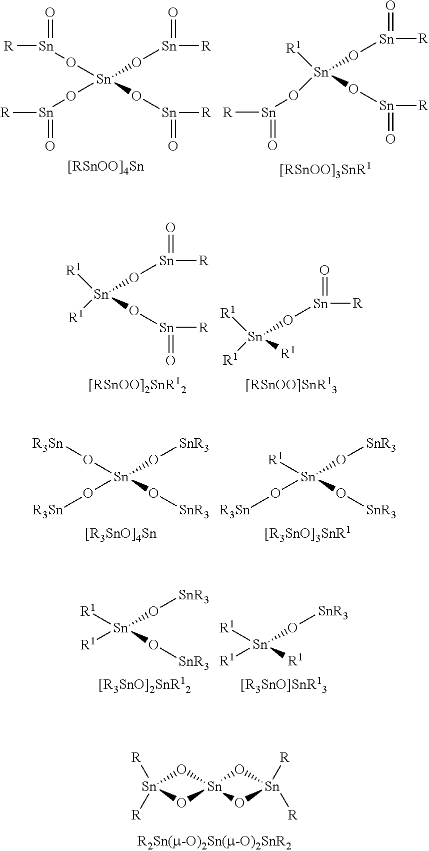
wherein R, R¹ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amine, cyclic amine, cyano, ether, cyclic ether, ester, cyclic ester, halide, nitro, silyl, thiol, or carbonyl group.

19. An organotin compound, having a chemical structure selected from the following: 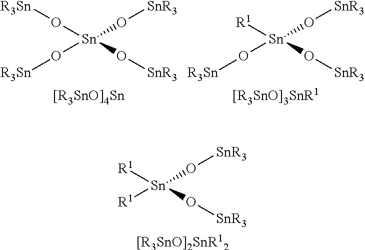
wherein R is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, R¹ is cyclopentadienyl, wherein cyclopentadienyl comprises cyclopentadienyl C₅H₅ group, or substituted cyclopentadienyl C₅H₄R², C₅H₃R²₂, C₅H₂R²₃, C₅HR²₄, or C₅R²₅ group with hapticity of η¹, η², η³, η⁴, or η⁵ of isomers, wherein R² is an alkyl, alkenyl, alkynyl, or cycloalkyl group with 1 to 20 carbon atoms, or an aryl group with 6-20 carbon atoms.

20. The organotin compound of claim 19, wherein R is alkyl, aryl, or cyclopentadienyl, R¹ is cyclopentadienyl; wherein cyclopentadienyl comprises cyclopentadienyl C₅H₅, or substituted cyclopentadienyl C₅H₄R², C₅H₃R²₂, C₅H₂R²₃, C₅HR²₄, or C₅R²₅, wherein R² is H, methyl, ethyl, propyl, n-butyl, t-butyl, phenyl, or benzyl.
